(19) United States
(12) Patent Application Publication
(10) Pub. No.: US 2024/0120302 A1
(43) Pub. Date: Apr. 11, 2024

(54) Techniques For Arranging Conductive Pads In Electronic Devices

(71) Applicant: Intel Corporation, Santa Clara, CA (US)

(72) Inventors: Krishna Bharath Kolluru, Portland, OR (US); Atul Maheshwari, Portland, OR (US); Mahesh Kumashikar, Bangalore (IN); Md Altaf Hossain, Portland, OR (US); Ankireddy Nalamalpu, Portland, OR (US); Omkar Karhade, Chandler, AZ (US)

(73) Assignee: Intel Corporation, Santa Clara, CA (US)

(21) Appl. No.: 18/543,749

(22) Filed: Dec. 18, 2023

(51) Int. Cl. H01L 23/00; H01L 23/498

(52) U.S. Cl. CPC H01L 24/06; H01L 23/49838; H01L 24/05; H01L 24/16; H01L 24/17; H01L 25/0655; H01L 2224/05554; H01L 2224/05555; H01L 2224/06131; H01L 2224/16145; H01L 2224/16227; H01L 2224/17181

(57) ABSTRACT

An electronic device includes first and second external conductive pads coupled to route a first signal and third and fourth external conductive pads. The third and the fourth external conductive pads are between the first and the second external conductive pads on a surface of the electronic device.

### TECHNICAL FIELD

The present disclosure relates to electronic devices, and more particularly to techniques for arranging conductive pads in electronic devices.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the integrated circuit to perform the functions of the custom circuit design. Configurable integrated circuits can be used for co-processing in big-data or fast-data applications. For example, configurable integrated circuits can used in application acceleration tasks in a datacenter and can be reprogrammed during datacenter operation to perform different tasks.

### BRIEF DESCRIPTION OF DRAWINGS

FIG. 1 is a diagram that depicts an example of a portion of an integrated circuit die that includes external conductive pads.

FIG. 2 is a diagram that depicts another example of a portion of an integrated circuit die that includes external conductive pads.

FIG. 3A is a diagram that depicts an example of an integrated circuit (IC) die that includes buffer circuits and external conductive pads.

FIG. 3B is a diagram that depicts a circuit system that includes two integrated circuit (IC) dies that are coupled to an interposer through conductive bumps.

FIG. 4 is a diagram of an illustrative example of a configurable integrated circuit (IC).

FIG. 5 illustrates a block diagram of a system that can be used to implement a circuit design to be programmed onto a programmable logic device using design software.

FIG. 6 is a diagram that depicts an example of a programmable logic device that includes a fabric die and a base die that are connected to one another via microbumps.

FIG. 7 is a block diagram illustrating a computing system configured to implement one or more aspects of the embodiments described herein.

### DETAILED DESCRIPTION

In many types of electronic devices, a large defect can occur that affects several external conductive pads of an integrated circuit die during the manufacturing process. A manufacturing defect that is large (e.g., 54×54 micrometers) with respect to the pitch between the pads (e.g. 9×9 micrometers) can result in a significant yield loss for the integrated circuit dies (e.g., about 12%), even with repair techniques that add overhead in area (e.g., about 12.5%). Many types of previously known techniques for repairing manufacturing defects that affect conductive pads in integrated circuit dies are difficult to modify for larger defects. As a result, it can be difficult to improve yield for batches of integrated circuit dies having a significant amount of large manufacturing defects.

According to some examples disclosed herein, techniques are provided for manufacturing an integrated circuit die that increase the resiliency of the integrated circuit die to large manufacturing defects that affect external conductive pads of the integrated circuit die. According to these techniques, external conductive pads of the integrated circuit die that route the same signal or voltage are spread across a larger area of the integrated circuit die to increase resiliency to large defects. For example, a signal or voltage can be routed through two rows of external conductive pads that are separated by other rows of external conductive pads routing other signals or voltages on a surface of the integrated circuit die. These techniques can provide a scalable redundancy architecture for external conductive pads and conductive bumps with low or no repair overhead and significantly reduced physical design complexity. These techniques can provide flexibility in scaling pad architectures to resolve large defect sizes and can resolve large defect sizes in a pad limited circuit design for an integrated circuit.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. As used herein, “hard logic” generally refers to circuits in an integrated circuit device that are not configurable by an end user. The circuits in an integrated circuit device (e.g., in a configurable logic IC) that are configurable by the end user are referred to as “soft logic.”

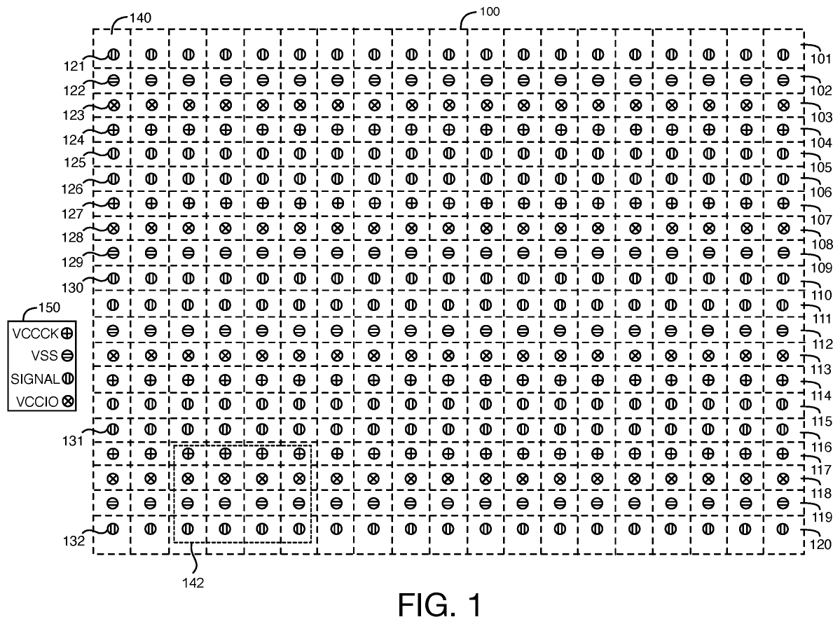

FIG. 1 is a diagram that depicts an example of a portion of an integrated circuit die 100 that includes external conductive pads. IC die 100 is also referred to herein as IC 100. IC 100 can be any type of integrated circuit (IC), such as a configurable IC (e.g., a field programmable gate array (FPGA) or programmable logic device), a microprocessor IC, a graphics processing unit IC, a memory IC, an application specific IC, a transceiver IC, a memory IC, etc.

FIG. 1 shows a top down (or bottom up) view of an external surface of the portion of integrated circuit (IC) die 100. The external conductive pads are exposed at the external surface of IC 100 for connecting internal circuitry of IC 100 to other electronic devices (such as an interposer) through conductive connections, such as conductive balls or bumps. The external conductive pads are shown in FIG. 1 as circles. However, in other implementations, external conductive pads arranged according to the techniques disclosed herein can have any desired shape, such as square, oval, or rectangular shapes.

FIG. 1 illustrates 380 external conductive pads (also referred to herein simply as pads or conductive pads) that are arranged in 19 vertical columns and 20 horizontal rows labeled 101-120. The rows and columns of pads are delineated by dotted lines in FIG. 1 for clarity. Although, it should be understood that the techniques disclosed herein apply to integrated circuits having any number of external conductive pads in any arrangement. The rows and/or columns of pads can be associated with any underlying circuitry in IC 100. As a specific example, each set of 5 pads in each column can be coupled to a different receiver or a different transmitter in a different channel in a transceiver circuit in IC 100 that includes transmitters and receivers.

The external conductive pads in IC 100 are coupled to route (i.e., provide) signals and voltages, as shown by the diagram 150 on the left side of IC 100 in FIG. 1. Specifically, the external conductive pads in rows 102, 109, 112, and 119 are coupled to route a ground (or low) voltage VSS to circuitry in IC 100. The external conductive pads in rows 104, 107, 114, and 117 are coupled to route a clock supply voltage VCCCK to circuitry in IC 100. The external conductive pads in rows 103, 108, 113, and 118 are coupled to route an input/output supply voltage VCCIO to circuitry in IC 100. Voltages VSS, VCCIO, and VCCCK are held at nearly constant voltages that may have small variations caused by noise during operation of IC 100.

The external conductive pads in rows 101, 105-106, 110-111, 115-116, and 120 are coupled to route signals, such as data signals, control signals, or clock signals, between circuitry in IC 100 and one or more external devices. Each of these signals is routed through a pair of two of the external conductive pads. One of the pads in each pair functions as a redundant pad. The two external conductive pads in each pair are in the same column of pads but are in two different rows of pads. Each pair of external conductive pads that routes the same signal is separated by three other pads in the same column, but in three different rows, that route supply and ground voltages. Thus, three voltage pads are between each pair of pads that routes the same signal.

Column 140 identified in FIG. 1 includes pads 121-132. As an example, a first signal is routed through a pair of pads 121 and 125. Pad 121 is in row 101, and pad 125 is in row 105. Rows 101 and 105 are separated by rows 102, 103, and 104 of external conductive pads that route voltages VSS, VCCIO, and VCCCK, respectively. Three voltage pads 122-124 are between the signal pads 121 and 125 in column 140.

As another example, a second signal is routed through a pair of pads 126 and 130. Pad 126 is in row 106, and pad 130 is in row 110. Rows 106 and 110 are separated by rows 107, 108, and 109 of external conductive pads that route voltages VCCCK, VCCIO, and VSS, respectively. Three voltage pads 127-129 are between the signal pads 126 and 130 in column 140. As yet another example, a third signal is routed through a pair of pads 131-132. Pad 131 is in row 116, and pad 132 is in row 120. Rows 116 and 120 are separated by rows 117, 118, and 119 of external conductive pads that route voltages VCCCK, VCCIO, and VSS, respectively. Three pads that route voltages VCCCK, VCCIO, and VSS are between the pads 131 and 132 in column 140.

Because each of the signals is routed through a pair of external conductive pads that are separated by three voltage pads between the pair, the signal can be routed through at least one of the external conductive pads in the pair if a manufacturing defect affects one of the two external conductive pads in the pair and the three voltage pads. A manufacturing defect (e.g., an open circuit) can, for example, affect (e.g., disable) 4 consecutive external conductive pads in a single column in IC 100 without affecting both of the external conductive pads in a pair that route a signal. Only a defect that disables 5 or more consecutive pads in a single column could affect both pads in a pair separated by 4 pads and potentially prevent signal transmission through the pair of pads. Thus, placing three external conductive pads that route voltages between each pair of external conductive pads that transmit a signal increases the resiliency of IC 100 to manufacturing defects that are large enough to disable 4 consecutive pads in a single column. As an example, a manufacturing defect 142 shown in FIG. 1 that disables a 4 pad by 4 pad area (e.g., 36×36 micrometer area) on the surface of IC 100 would not prevent at least one of the signal pads in each pair of 4 pairs from being used to route a signal to or from circuitry in IC 100.

The pads that route the ground voltage VSS, such as the pads in rows 109 and 112, are separated by at least two other pads in the same column that route different signals. Some of the pads that route ground voltage VSS, such as pads 122 and 129, are separated by six other pads in the same column that route different voltages and signals. The pads that route supply voltage VCCIO, such as pads 123 and 128, are separated by four other pads in the same column that route different voltages and signals. The pads that route supply voltage VCCCK, such as pads 124 and 127, are separated by at least two other pads in the same column that route different signals. Some of the pads that route supply voltage VCCCK, such as pads in rows 107 and 114, are separated by six other pads in the same column that route different voltages and signals.

A manufacturing defect (e.g., an open circuit) can, for example, affect (e.g., disable) up to three consecutive external conductive pads in a single column of IC 100 without affecting two external conductive pads that route the same voltage. Only a defect that disables 4 or more consecutive pads in a single column could affect two pads separated by at least 2 other pads and potentially prevent voltage transmission through both of the two pads. Thus, placing two or more external conductive pads that route voltages or signals between two other external conductive pads that transmit a different voltage increases the resiliency of IC 100 to manufacturing defects that are large enough to disable 3 consecutive pads in a column. As an example, a manufacturing defect that disables a 3 pad by 3 pad area on the surface of IC 100 would not prevent at least one of the pads in each pair separated by at least two other pads from being used to route a voltage. The physical redundancy of the power and ground pads provides enough connectivity that defects disabling power or ground pads does not significantly impact the performance of IC 100.

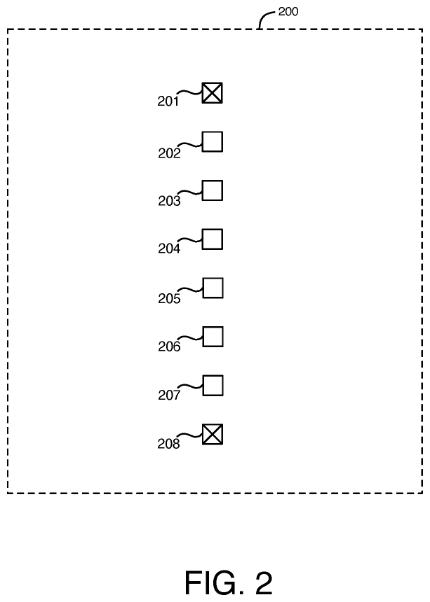

FIG. 2 is a diagram that depicts another example of a portion of an integrated circuit die 200 that includes external conductive pads. IC die 200 is also referred to herein as IC 200. IC 200 can be any type of integrated circuit (IC), such as a configurable IC (e.g., an FPGA or programmable logic device), a microprocessor IC, a graphics processing unit IC, a memory IC, an application specific IC, a transceiver IC, a memory IC, etc. The portion of IC 200 shown in FIG. 2 can, as an example, be a portion of IC 100.

FIG. 2 shows a top down (or bottom up) view of an external surface of the portion of IC 200. The external conductive pads are exposed at the external surface of IC 200 for connecting internal circuitry of IC 200 to other devices (such as an interposer) through conductive connections, such as conductive balls or bumps. The external conductive pads are shown in FIG. 2 as squares. However, in other implementations, external conductive pads arranged according to the techniques disclosed herein can have any desired shape, such as circular, oval, or rectangular shapes.

FIG. 2 illustrates 8 external conductive pads 201-208 (also referred to herein simply as pads or conductive pads) arranged in a single vertical column as an example. Although, IC 200 can have any number of additional external conductive pads. In the example of FIG. 2, external conductive pads 201 and 208 route a signal (e.g., a data signal, control signal, or clock signal) between circuitry in IC 200 and a device that is external to IC 200. The other 6 pads 202-207 can be used to route other signals, power supply voltages, or a ground voltage. As other examples, any 2 or more of the other 6 pads 202-207 can be used for sorting or as mechanical pads.

Because a signal is routed through a pair of external conductive pads 201 and 208 that are separated by 6 other pads 202-207, the signal can still be routed through at least one of external conductive pads 201 or 208 if a manufacturing defect affects one of pads 201 or 208. A manufacturing defect (e.g., a short or an open circuit) can, for example, affect (e.g., disable) 7 consecutive external conductive pads in the column of IC 200 without affecting both of pads 201 and 208. Only a single defect large enough to disable all 8 pads 201-208 could prevent signal transmission through both of pads 201 and 208. Thus, placing 6 external conductive pads 202-207 between a pair of external conductive pads 201 and 208 that transmit a signal increases the resiliency of IC 200 to manufacturing defects that are large enough to disable 7 consecutive pads in a single column. As an example, a manufacturing defect that disables a 6 pad by 6 pad area (e.g., 54×54 micrometer area) on the surface of IC 200 would not prevent at least one of the pads 201 or 208 from being used to route a signal to or from circuitry in IC 200.

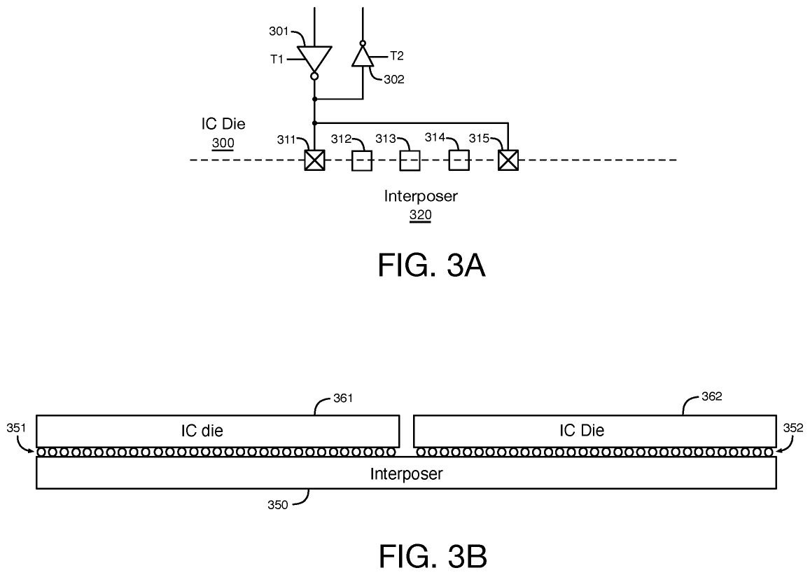

FIG. 3A is a diagram that illustrates an example of an integrated circuit (IC) die 300 that includes buffer circuits and external conductive pads. IC die 300 includes an output buffer circuit 301, an input buffer circuit 302, and 5 external conductive pads 311-315. IC 300 is coupled to an interposer 320 through the pads 311-315. Buffer circuits 301-302 are tri-state buffer circuits that are enabled and disabled in response to control signals T1-T2, respectively. Both of the buffer circuits 301-302 are coupled to pads 311 and 315. During an output mode, control signal T1 enables output buffer circuit 301 to transmit an output signal through pads 311 and 315, and control signal T2 disables input buffer circuit 302. During an input mode, control signal T2 enables input buffer circuit 302 to transmit an input signal from pads 311 and 315 to other circuitry in IC die 300, and control signal T1 disables output buffer circuit 301. Pads 312, 313, and 314 are placed between pads 311 and 315 to provide increased resiliency to large manufacturing defects that affect up to 4 consecutive pads. Pads 312, 313, and 314 can, as example, be used to route other signals, supply voltages, and/or a ground voltage.

FIG. 3B is a diagram that depicts a circuit system that includes two integrated circuit (IC) dies 361-362 coupled to an interposer 350 through conductive bumps 351-352. IC dies 100, 200, and 300 are examples of either or both of the IC dies 361-362. IC die 361 is coupled to interposer 350 through conductive bumps 351. IC die 362 is coupled to interposer 350 through conductive bumps 352. The conductive bumps 351-352 can be, as examples, microbumps or hybrid bonding interconnects. Conductive bumps 351 are coupled between external conductive pads exposed on a surface of IC die 361 and conductive pads on the top surface of interposer 350. Conductive bumps 352 are coupled between external conductive pads exposed on a surface of IC die 362 and conductive pads on the top surface of interposer 350. The external conductive pads of IC dies 361-362 can be arranged according to the techniques disclosed herein with respect to FIGS. 1, 2 and/or 3A.

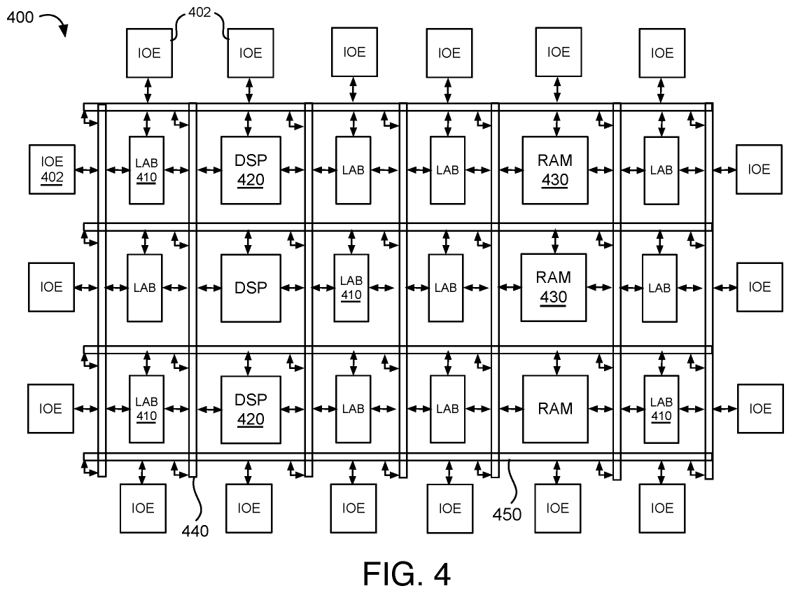

FIG. 4 is a diagram of an illustrative example of a configurable integrated circuit (IC) 400. Configurable IC 400 is an example of an IC that can include the pads and circuitry disclosed herein with respect to FIGS. 1, 2 and/or 3A. As shown in FIG. 4, the configurable integrated circuit 400 includes a two-dimensional array of configurable functional blocks, including logic array blocks (LABs) 410 and other functional blocks, such as random access memory (RAM) blocks 430 and digital signal processing (DSP) blocks 420, for example. Configurable functional blocks, such as LABs 410, can include smaller configurable regions (e.g., configurable logic elements, configurable logic blocks, or adaptive logic modules) that receive input signals and perform custom functions on the input signals to produce output signals.

The configurable integrated circuit 400 also includes programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire. One or more of the routing channels 440 and/or 450 can be part of a network-on-chip (NOC) having router circuits.

In addition, the configurable integrated circuit 400 has input/output elements (IOEs) 402 for driving signals off of configurable integrated circuit 400 and for receiving signals from other devices. Input/output elements 402 can include parallel input/output circuitry, serial data transceiver circuitry, differential receiver and transmitter circuitry, or other circuitry used to connect one integrated circuit to another integrated circuit. Input/output elements 402 can include general purpose input/output (GPIO) circuitry (e.g., on the top and bottoms edges of IC 400), high-speed input/output (HSIO) circuitry (e.g., on the left edge of IC 400), and on-package input/output (OPIOs) circuitry (e.g., on the right edge of IC 400).

As shown, input/output elements 402 can be located around the periphery of the IC. If desired, the configurable integrated circuit 400 can have input/output elements 402 arranged in different ways. For example, input/output elements 402 can form one or more columns of input/output elements that can be located anywhere on the configurable integrated circuit 400 (e.g., distributed evenly across the width of the configurable integrated circuit). If desired, input/output elements 402 can form one or more rows of input/output elements (e.g., distributed across the height of the configurable integrated circuit). Alternatively, input/output elements 402 can form islands of input/output elements that can be distributed over the surface of the configurable integrated circuit 400 or clustered in selected areas.

Note that other routing topologies, besides the topology of the interconnect circuitry depicted in FIG. 4, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 400 can also contain programmable memory elements. The memory elements can be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector can include the configuration bits that specify the function and/or interconnections of the subcomponents and wires in or crossing that sector. Each sector can include separate data and address registers.

The configurable IC 400 of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

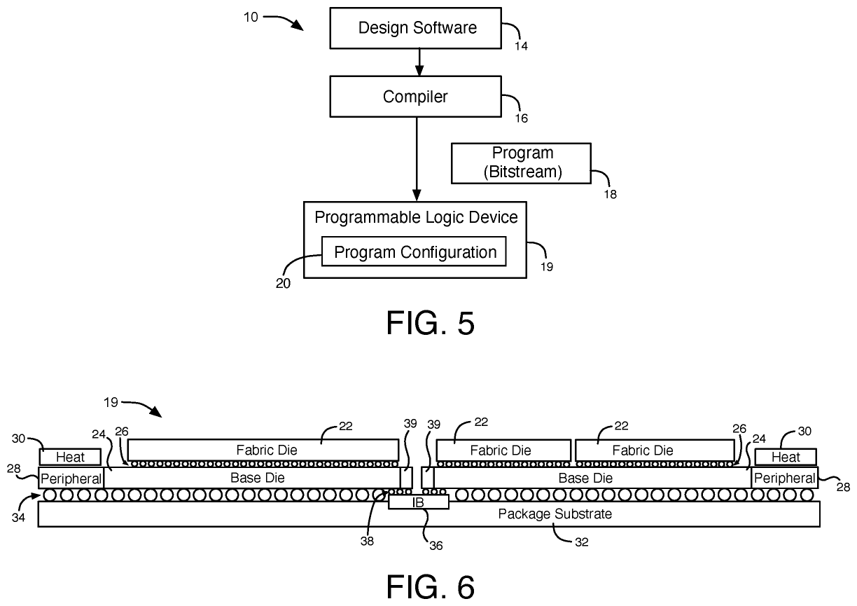

FIG. 5 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6, but many others can be used, and it should be understood that this disclosure is intended to encompass any suitable programmable logic device where programmable logic fabric and fabric support circuitry are at least partially separated on different integrated circuit die.

FIG. 6 is a diagram that depicts an example of the programmable logic device 19 that includes three fabric die 22 and two base die 24 that are connected to one another via microbumps 26. In the example of FIG. 6, at least some of the programmable logic fabric of the programmable logic device 19 is in the three fabric die 22, and at least some of the fabric support circuitry that operates the programmable logic fabric is in the two base die 24. For example, some of the circuitry of configurable IC 400 shown in FIG. 4 (e.g., LABs 410, DSP 420, and RAM 430) can be located in the fabric die 22 and some of the circuitry of IC 400 (e.g., input/output elements 402) can be located in the base die 24.

Although the fabric die 22 and base die 24 appear in a one-to-one relationship or a two-to-one relationship in FIG. 6, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

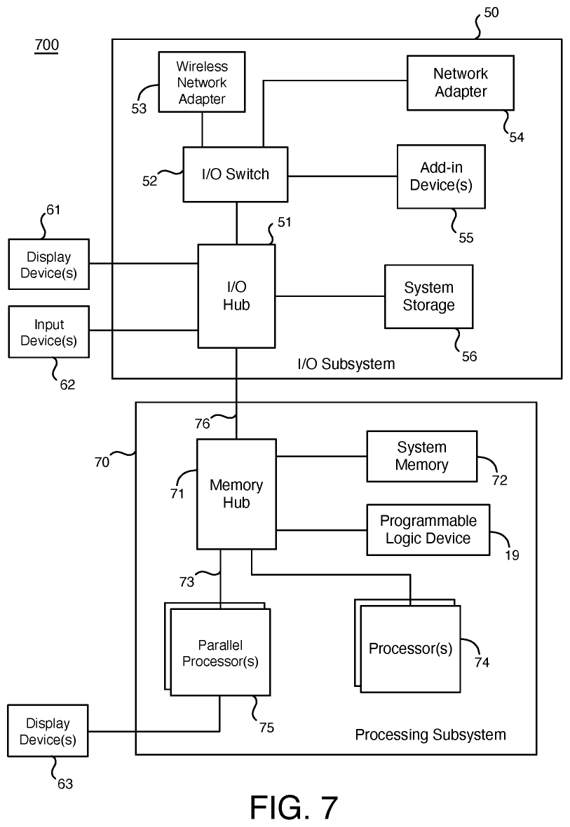

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an electronic device comprising: first and second external conductive pads coupled to route a first signal; and third and fourth external conductive pads, wherein the third and the fourth external conductive pads are between the first and the second external conductive pads on a surface of the electronic device.

In Example 2, the electronic device of Example 1 can optionally include, wherein the third external conductive pad is coupled to route a first voltage.

In Example 3, the electronic device of Example 2 can optionally include, wherein the fourth external conductive pad is coupled to route a second voltage.

In Example 4, the electronic device of any one of Examples 1-3 further comprises: a fifth external conductive pad between the first and the second external conductive pads on the surface of the electronic device, wherein the third external conductive pad is coupled to route a first supply voltage, the fourth external conductive pad is coupled to route a second supply voltage, and the fifth external conductive pad is coupled to route a ground voltage.

In Example 5, the electronic device of any one of Examples 1˜4 can optionally include, wherein the first, the second, the third, and the fourth external conductive pads are arranged in a column on the surface of the electronic device.

In Example 6, the electronic device of any one of Examples 1-5 further comprises: fifth and sixth external conductive pads coupled to route a second signal; and seventh and eighth external conductive pads, wherein the seventh and the eighth external conductive pads are between the fifth and the sixth external conductive pads on the surface of the electronic device.

In Example 7, the electronic device of any one of Examples 1-6 can optionally include, wherein the electronic device is one of an integrated circuit or an interposer.

In Example 8, the electronic device of any one of Examples 1-7 further comprises: a buffer circuit coupled to the first and the second external conductive pads, wherein the buffer circuit is coupled to drive or receive the first signal through the first and the second external conductive pads.

Example 9 is a method for increasing resiliency of an electronic device to defects, the method comprising: providing first and second conductive pads that are each coupled for transmitting a first signal and that are exposed on a surface of the electronic device; and providing third and fourth conductive pads between the first and the second conductive pads that are exposed on the surface of the electronic device.

In Example 10, the method of Example 9 can optionally include, wherein the third conductive pad is coupled for transmitting a first voltage.

In Example 11, the method of Example 10 further comprises: providing a fifth conductive pad between the first and the second conductive pads that is exposed on the surface of the electronic device.

In Example 12, the method of Example 11 can optionally include, wherein the first voltage is a first supply voltage, the fourth conductive pad is coupled for transmitting a second supply voltage, and the fifth conductive pad is coupled for transmitting a ground voltage.

In Example 13, the method of any one of Examples 9-12 further comprises: providing fifth and sixth conductive pads that are each coupled for transmitting a second signal and that are exposed on the surface of the electronic device; and providing seventh, eighth, and ninth conductive pads between the fifth and the sixth conductive pads, wherein the seventh, the eighth, and the ninth conductive pads are exposed on the surface of the electronic device.

In Example 14, the method of Example 13 can optionally include, wherein the seventh conductive pad is coupled for transmitting a first supply voltage, wherein the eighth conductive pad is coupled for transmitting a second supply voltage, and wherein the ninth conductive pad is coupled for transmitting a ground voltage.

In Example 15, the method of any one of Examples 9-14 can optionally include, wherein the first, the second, the third, and the fourth conductive pads are arranged consecutively on the surface of the electronic device.

Example 16 is an electronic device comprising: a first row of first conductive pads coupled for providing a first voltage; a second row of second conductive pads coupled for providing a second voltage, wherein the second row is next to the first row on a surface of the electronic device; and a third row of third conductive pads coupled for providing a third voltage, wherein the third row is next to the second row on the surface of the electronic device.

In Example 17, the electronic device of Example 16 further comprises: a fourth row of fourth conductive pads coupled for providing a signal between circuitry in the electronic device and an external device, wherein the fourth row is next to the third row on the surface of the electronic device.

In Example 18, the electronic device of any one of Examples 16-17 further comprises: a fourth row of fourth conductive pads coupled for providing a signal; and a fifth row of fifth conductive pads coupled for providing the signal, wherein the fourth row is next to the third row on the surface of the electronic device, and wherein the fifth row is next to the first row on the surface of the electronic device.

In Example 19, the electronic device of any one of Examples 16-18 can optionally include, wherein the electronic device is one of an integrated circuit or an interposer.

In Example 20, the electronic device of any one of Examples 16-19 can optionally include, wherein the first voltage is a first supply voltage, the second voltage is a second supply voltage, and the third voltage is a ground voltage.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An electronic device comprising:
first and second external conductive pads coupled to route a first signal; and
third and fourth external conductive pads, wherein the third and the fourth external conductive pads are between the first and the second external conductive pads on a surface of the electronic device.

2. The electronic device of claim 1, wherein the third external conductive pad is coupled to route a first voltage.

3. The electronic device of claim 2, wherein the fourth external conductive pad is coupled to route a second voltage.

4. The electronic device of claim 1 further comprising: a fifth external conductive pad between the first and the second external conductive pads on the surface of the electronic device, wherein the third external conductive pad is coupled to route a first supply voltage, the fourth external conductive pad is coupled to route a second supply voltage, and the fifth external conductive pad is coupled to route a ground voltage.

5. The electronic device of claim 1, wherein the first, the second, the third, and the fourth external conductive pads are arranged in a column on the surface of the electronic device.

6. The electronic device of claim 1 further comprising:
fifth and sixth external conductive pads coupled to route a second signal; and
seventh and eighth external conductive pads, wherein the seventh and the eighth external conductive pads are between the fifth and the sixth external conductive pads on the surface of the electronic device.

7. The electronic device of claim 1, wherein the electronic device is one of an integrated circuit or an interposer.

8. The electronic device of claim 1 further comprising:
a buffer circuit coupled to the first and the second external conductive pads, wherein the buffer circuit is coupled to drive or receive the first signal through the first and the second external conductive pads.

9. A method for increasing resiliency of an electronic device to defects, the method comprising:
providing first and second conductive pads that are each coupled for transmitting a first signal and that are exposed on a surface of the electronic device; and
providing third and fourth conductive pads between the first and the second conductive pads that are exposed on the surface of the electronic device.

10. The method of claim 9, wherein the third conductive pad is coupled for transmitting a first voltage.

11. The method of claim 10 further comprising:
providing a fifth conductive pad between the first and the second conductive pads that is exposed on the surface of the electronic device.

12. The method of claim 11, wherein the first voltage is a first supply voltage, the fourth conductive pad is coupled for transmitting a second supply voltage, and the fifth conductive pad is coupled for transmitting a ground voltage.

13. The method of claim 9 further comprising:
providing fifth and sixth conductive pads that are each coupled for transmitting a second signal and that are exposed on the surface of the electronic device; and
providing seventh, eighth, and ninth conductive pads between the fifth and the sixth conductive pads, wherein the seventh, the eighth, and the ninth conductive pads are exposed on the surface of the electronic device.

14. The method of claim 13, wherein the seventh conductive pad is coupled for transmitting a first supply voltage, wherein the eighth conductive pad is coupled for transmitting a second supply voltage, and wherein the ninth conductive pad is coupled for transmitting a ground voltage.

15. The method of claim 9, wherein the first, the second, the third, and the fourth conductive pads are arranged consecutively on the surface of the electronic device.

16. An electronic device comprising:
a first row of first conductive pads coupled for providing a first voltage;
a second row of second conductive pads coupled for providing a second voltage, wherein the second row is next to the first row on a surface of the electronic device; and
a third row of third conductive pads coupled for providing a third voltage, wherein the third row is next to the second row on the surface of the electronic device.

17. The electronic device of claim 16 further comprising:
a fourth row of fourth conductive pads coupled for providing a signal between circuitry in the electronic device and an external device, wherein the fourth row is next to the third row on the surface of the electronic device.

18. The electronic device of claim 16 further comprising:
a fourth row of fourth conductive pads coupled for providing a signal; and
a fifth row of fifth conductive pads coupled for providing the signal,
wherein the fourth row is next to the third row on the surface of the electronic device, and wherein the fifth row is next to the first row on the surface of the electronic device.

19. The electronic device of claim 16, wherein the electronic device is one of an integrated circuit or an interposer.

20. The electronic device of claim 16, wherein the first voltage is a first supply voltage, the second voltage is a second supply voltage, and the third voltage is a ground voltage.
